(19) United States
(12) Patent Application Publication
(10) Pub. No.: US 2026/0246463 A1
(43) Pub. Date: Aug. 20, 2026

(54) DEMAGNETIZATION MECHANISM FOR ISOLATED GATE DRIVERS

(71) Applicant: Allegro MicroSystems, LLC, Manchester, NH (US)

(72) Inventors: Guillaume Aulagnier, Cannes (FR); John Horan, Cork (IE)

(73) Assignee: Allegro MicroSystems, LLC, Manchester, NH (US)

(21) Appl. No.: 19/058,577

(22) Filed: Feb. 20, 2025

(51) Int. Cl. H03K 17/687

(52) U.S. Cl. CPC H03K 17/6874

(57) ABSTRACT

Magnetically isolated gate drivers include primary side gate drivers configured to produce demagnetization voltages that counter integrated flux resulting from refresh pulses sent through the transformer. A magnetically-isolated gate driver circuit includes an isolation transformer including a primary coil and a secondary coil configured about a magnetic core, control circuitry including a control signal pulse generator configured to produce refresh power pulses and including a demagnetization circuit, connected to the primary coil; where the demagnetization circuit is configured to produce demagnetization pulses to demagnetize or mitigate against saturation of the magnetic core.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to separate voltage potentials. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

For magnetically coupled isolated gate drivers, a challenge arises when transferring power and signal to the high side of the circuit (where “high-side” refers to the device being placed between the positive power line and the load in the circuit), particularly at low frequencies. At lower frequencies, the incoming signal pulses may not occur frequently enough to sustain a minimum power level on the high side of the driver circuit. This minimum power level can be crucial for maintaining appropriate logic and bias conditions. To address this issue, one approach involves generating refresh pulses sent to the high side to ensure a consistent power level.

FIGS. 1A-1B show a circuit diagram and two timing diagrams, respectively for a prior art galvanically-isolated gate driver 100. Gate driver 100 includes an input 101 configured to receive one or more control pulses 102, and pulse generator 103. Pulse generator 103 is configured to receive the control pulse(s) 102 and generate corresponding positive signal pulse(s) S_{P} 104 and negative signal pulse(s) S_{N} 105, which are provided to transformer 106 at the primary side (coil) 107, e.g., via first and second CMOS inverters 109, 110, respectively. The secondary side (coil) 108 of transformer 106 provides the positive signal pulse(s) S_{P} 104 and negative signal pulse(s) S_{N} 105 to rectifier 111 and signal detector (signal detect block) 112 via connections as shown. Rectifier 111 is configured to provide power to high-side circuitry at connections 111a-111b, e.g., for driven device 120. A signal detector 112 is configured to provide an output voltage signal 113 at connections 112a-112b, which may be used for control of, e.g., for driven device 120. The scheme shown in FIG. 1A sends power and a signal to the high side circuitry, where “high side” refers to the circuitry being placed between the positive power line and the load in the circuit.

As shown in FIG. 1B, the pulses seen at S_{P} (positive signal pulse) and S_{N} (negative signal pulse) are sent across the magnetic isolation boundary provided by transformer 106 and are used to set and reset a latch in the signal detect block 112 and thus generate the input signal (for controlling the device to be switched).

The scheme can work well when the positive and negative signal pulses (S_{P} and S_{N}) generated by the input signal (V_{IN}) occur frequently. This allows adequate power to be harvested by the high side rectifier 111 to power the bias and logic circuits on the high side.

When the frequency of the incoming signal (e.g., V_{IN} 102) is too low, however, the signal pulses (S_{P} and S_{N}) do not occur frequently enough to supply sufficient power to the high-side circuitry. For this reason, additional pulses, called refresh pulses, are typically generated which further pulse energy across the transformer 106 and maintain the power level in the system. The pulse generator (generation) circuit in FIG. 1A accepts the refresh pulse and passes it through to generate the pulse that impacts the S_{P} node. The scheme is sensible in that the refresh pulse R_{P} is sent as a positive pulse and this only reaffirms the latch in the high side signal detect block 112.

A drawback often occurs when circuit 100 in FIG. 1 operates with a long T_{ON} (or T_{OFF}) time span, as the transformer receives multiple refresh pulses, all with the same polarity. The flux of the transformer integrates this unipolar excitation, creating a significant risk of saturation of the transformer core. A saturated magnetic core can lead to problems, including but not limited to a significant decrease in inductance, causing distorted waveforms, increased harmonic distortion, excessive heat generation, and potential damage to the associated circuitry due to large inrush currents.

### SUMMARY

Aspects of the present disclosure are directed to demagnetization techniques for magnetically isolated gate drivers.

In one aspect, a magnetically-isolated gate driver circuit providing core saturation protection, wherein the gate driver circuit is configured to control a semiconductor power switch, the circuit comprising: an isolation transformer including a primary coil and a secondary coil configured about a magnetic core, wherein the isolation transformer provides galvanic separation of low and high sides of the gate driver circuit; control circuitry, including a control signal pulse generator having an input and a demagnetization circuit, connected to the primary coil, wherein the control signal pulse generator is configured to receive control signals (V_{IN}) at the input and generate corresponding positive and negative control signal pulses; wherein the control circuitry is configured to produce refresh pulses having a first polarity and first voltage amplitude to provide necessary power for the gate driver circuit; and wherein the demagnetization circuit is configured to produce demagnetization pulses having a second polarity and a second voltage amplitude to demagnetize the magnetic core, wherein the second polarity is opposite the first polarity and wherein second voltage amplitude is less than the first voltage amplitude; a rectifier connected to the secondary coil, wherein the rectifier is configured to harvest power from the pulses received by the secondary coil and provide power to the high side of the gate driver circuit; and a signal detector connected to the secondary coil and configured to detect the control signal pulses and based on the detected control signal pulses provide isolated control signals for control of the semiconductor power switch.

A circuit can further include one or more of the following features: the demagnetization circuit is configured to produce one or more demagnetization pulses after each control signal pulse is produced, each refresh pulse has a first duration and wherein each demagnetization pulse has a second duration, wherein the second duration is greater than the first duration, the demagnetization circuit includes first and second pre-drivers configured to provide demagnetization pulses of opposite polarity, respectively, the control circuitry further includes a logic unit configured to control the first and second pre-drivers, each of the first and second pre-drivers comprises a voltage divider having first and second resistors, the control signal pulse generator comprises first and second power field effect transistors (FETs), the first and second power FETs are configured to dissipate power from the demagnetization pulses, the signal detector includes a latch, wherein positive and negative pulses received from the secondary coil operate to set and reset the latch to form the control signal pulses, and/or a first semiconductor power switch connected to the secondary coil, wherein the gate driver circuit is configured to control operation of the first semiconductor power switch.

In another aspect, a method of making a magnetically-isolated gate driver circuit providing core saturation protection, wherein the gate driver circuit is configured to control a semiconductor power switch, the method comprising: providing an isolation transformer including a primary coil and a secondary coil configured about a magnetic core, wherein the isolation transformer provides galvanic separation of low and high sides of the gate driver circuit; providing control circuitry, including a control signal pulse generator having an input and a demagnetization circuit, connected to the primary coil, wherein the control signal pulse generator is configured to receive control signals (V_{IN}) at the input and generate corresponding positive and negative control signal pulses; wherein the control circuitry is configured to produce refresh pulses having a first polarity and a first voltage amplitude to provide necessary power for the gate driver circuit; and wherein the demagnetization circuit is configured to produce demagnetization pulses having a second polarity and a second voltage amplitude to demagnetize the magnetic core, wherein the second polarity is opposite the first polarity and wherein second voltage amplitude is less than the first voltage amplitude; providing a rectifier connected to the secondary coil, wherein the rectifier is configured to harvest power from the pulses received by the secondary coil and provide power to the high side of the gate driver circuit; and providing a signal detector connected to the secondary coil and configured to detect the control signal pulses and based on the detected control signal pulses provide isolated control signals for control of the semiconductor power switch.

A method can further include one or more of the following features: the demagnetization circuit is configured to produce one or more demagnetization pulses after each control signal pulse is produced, each refresh pulse has a first duration and wherein each demagnetization pulse has a second duration, wherein the second duration is greater than the first duration, the demagnetization circuit includes first and second pre-drivers configured to provide demagnetization pulses of opposite polarity, respectively, the control circuitry further includes a logic unit configured to control the first and second pre-drivers, each of the first and second pre-drivers comprises a voltage divider having first and second resistors, the control signal pulse generator comprises first and second power field effect transistors (FETs), the first and second power FETs are configured to dissipate power from the demagnetization pulses, the signal detector includes a latch, wherein positive and negative pulses received from the secondary coil operate to set and reset the latch to form the control signal pulses, and/or a first semiconductor power switch connected to the secondary coil, wherein the gate driver circuit is configured to control operation of the first semiconductor power switch.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitations in the figures, in which:

FIGS. 1A-1B show circuit and timing diagrams for a prior art galvanically-isolated gate driver;

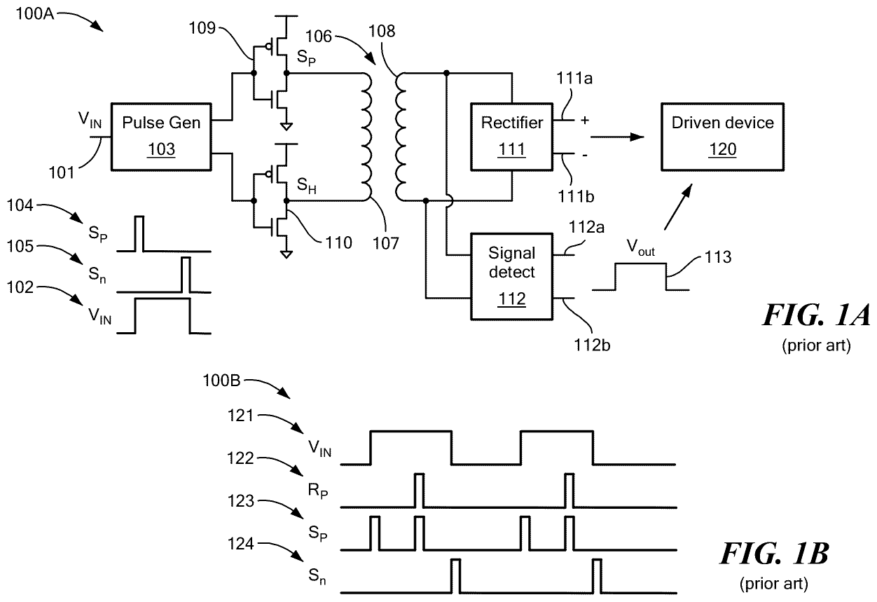

FIG. 2 is circuit diagram of a simplified transformer model;

FIGS. 3A-3B show timing and circuit diagrams for an example demagnetization circuit, in accordance with the present disclosure;

FIGS. 4A-4B show diagrams of an example low-side driver circuit providing core demagnetization, in accordance with the present disclosure;

FIG. 5 is a diagram showing an example method of fabricating driver circuits providing core demagnetization, in accordance with the present disclosure; and

FIG. 6 is a diagram of an example computing system in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects, examples, and embodiments of the present disclosure are directed to and include magnetically-isolated gate driver circuits, assemblies, structures, and packages and related fabrication methods, which provide demagnetization techniques to mitigate magnetic core saturation.

Such assemblies, structures, and packages can be used for systems, structures, and circuits for galvanic isolation (a.k.a., voltage isolation) used, for high-voltage applications, e.g., power modules of electric vehicles (EVs). In some embodiments, a transformer with a core may have, e.g., a step up, a step down, or a power transformer configuration. In some embodiments, a transformer may have multiple input and/or output coils/coil structures.

Transformer assemblies and packages (modules) may include various types of circuits (e.g., ICs); in some examples, transformer packages with ICs may include a galvanically isolated gate driver or other high voltage circuit, etc. One or more (e.g., first and second) semiconductor die having one or more integrated circuits (a.k.a., “IC die”) can be included in the packages and assemblies. Such integrated circuits can include, e.g., but are not limited to, high-voltage circuits such as galvanically-isolated gate drivers configured to drive an external gate on a solid-state (semiconductor) switch, e.g., a field effect transistor (FET), a metal oxide semiconductor (MOS) FET (MOSFET), a metal semiconductor FET (MESFET), a gallium nitride FET (GaN FET), a high electron mobility transistor (HEMT), a silicon carbide FET (SiC FET), an insulated gate bipolar transistor (IGBT), or another load.

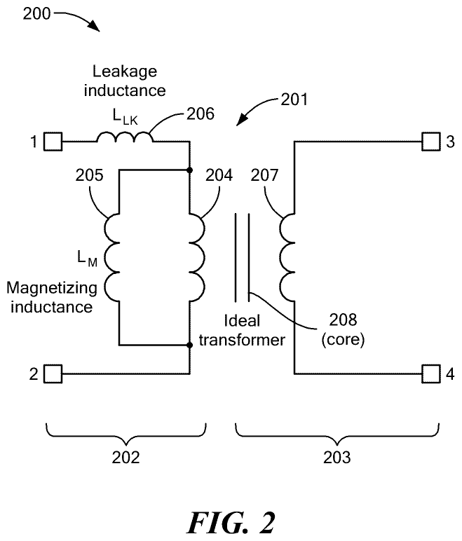

FIG. 2 is circuit diagram of a simplified transformer model 200. Modeled transformer circuit 200 includes transformer 201 with primary side 202 and secondary side 203. Primary side 202 includes primary coil 204, which includes one or more windings, and terminals 1 and 2. Magnetizing inductance (L_{M}) of primary coil 204 is indicated as 205. Leakage inductance (L_{LK}) of primary coil 204 is indicated as 206. Secondary side 203 includes secondary coil 207, which includes one or more windings, and terminals 3 and 4. Magnetic core 208 is also present. The flux in the transformer is proportional to the current in the magnetizing inductance (L_{M}) 205 of the modeled transformer 201.

As noted above for prior art (circuit 100), in the case where circuit 200 operates with control signal pulses (provided at terminals 1-2) having a long ON time (T_{ON}) or OFF time (T_{OFF}), the transformer 201 receives multiple refresh pulses, all with the same polarity. In that case, the flux of the transformer 201 would integrate this unipolar excitation, creating a risk of saturation of the magnetic core 208. Aspects and embodiments of the present disclosure provide demagnetization mechanisms/techniques that can mitigate or eliminate saturation of magnetic cores that would otherwise occur due to refresh pulses.

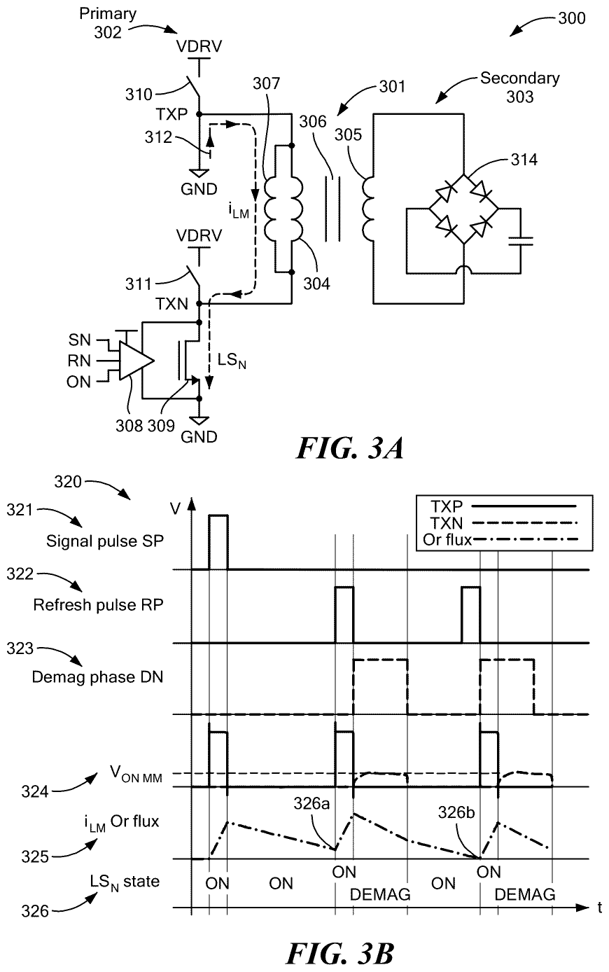

FIGS. 3A-3B are timing and circuit diagrams for an example demagnetization circuit 300, in accordance with the present disclosure.

As shown in FIG. 3A, circuit 300 includes transformer 301 with primary side 302 and secondary side 303. Primary side 302 includes primary coil 304, which includes one or more windings. Secondary side 303 includes secondary coil 305, which includes one or more windings. The respective number of windings of primary coil 304 and secondary coil 305 can be selected as desired (e.g., to implement a desired transformer ratio, η). Transformer 301 further includes magnetic core 306, which may be made of or include any suitable material, e.g., soft ferromagnetic material. Magnetizing inductance (L_{M}) of primary coil 304 is indicated as 307. Circuit 300 includes pre-driver 308 which is configured to drive low-side device 309 (e.g., a switch such as power FET). Switches 310, 311 on high-side and low-side, respectively, are also indicated. The high-side device (e.g., power FET) is omitted for clarity in showing the magnetizing inductance current (I_{LM}) 312, which generates the flux of the transformer 301. Secondary side 302 is shown including diode bridge 312. Circuit 300, utilizing pre-driver 308, is designed to generate demagnetization voltage pulses to mitigate core saturation that would otherwise arise from refresh pulses, which may be produced by circuit 300 or another circuit/circuitry.

In FIG. 3B, a control signal pulse (S_{P}) is shown at 321 and refresh pulses (R_{P}) are shown at 322. Demagnetization voltage phases (DN) and demagnetization pulses are shown at 323 and 324, respectively. The demagnetization voltage pulses are generated at the opposite side of the transformer 301 after each refresh pulse (R_{P}). The demagnetization voltage preferably has an amplitude smaller than that of the refresh pulses (R_{P}) to prevent the demagnetization pulses from being considered as signal and/or refresh pulses. In the example shown, a demagnetization phase DN 323 is indicated after each refresh pulse (R_{P}). Line 325 indicates the magnetizing inductance current (I_{LM}) or flux. The state of the low-side device is indicated at 326.

The demagnetization voltage across the transformer 301 creates a greater slope of decay of the flux, as shown at 325. Accordingly, the demagnetization voltage helps resetting the flux in between refresh pulses (R_{P}), mitigating or avoiding the risk of saturation of the transformer core 306. The demagnetizing voltage is preferably low enough to not be interpreted as a pulse in the opposite direction at the secondary side of the transformer. In some embodiments, the generated voltage is low enough to always be differentiated from a refresh pulse.

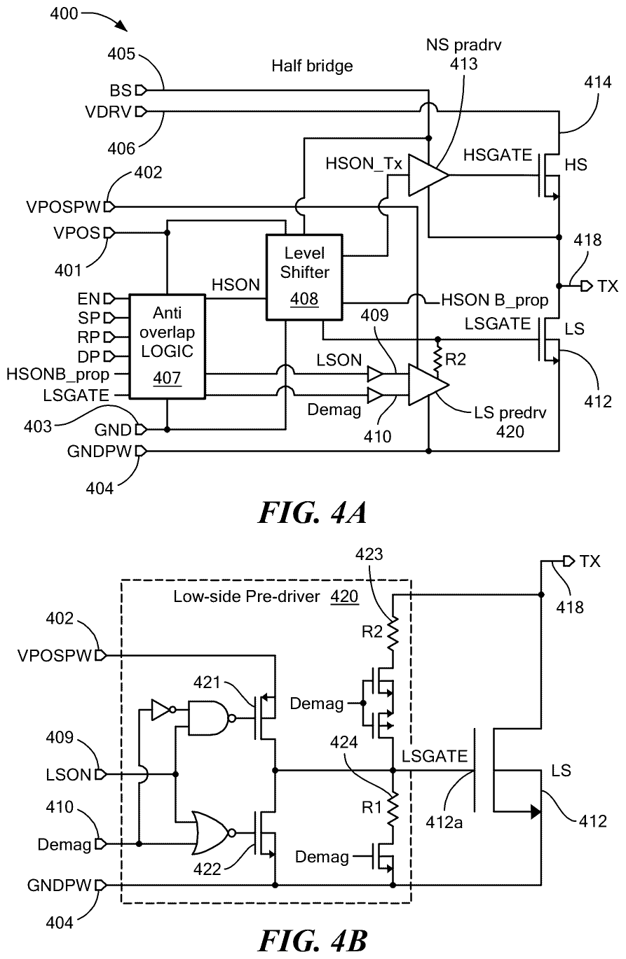

FIGS. 4A-4B show diagrams of an example low-side driver circuit 400 providing core demagnetization, in accordance with the present disclosure.

As shown in FIG. 4A, circuit 400 can include terminals for positive voltage (VPOS) 401, positive signal (e.g. PWM) voltage (VPOSPW) 402, ground (GND) 403, signal ground (GNDPW) 404, bias voltage (BS) 405, gate drive voltage (VDRV) 406, and transformer primary side voltage (TX) 418. Circuit 400 also includes controller 407, level shifter 408, high-side pre-driver 413, high-side device (power FET) 414, low-side device (power FET) 412, and low-side pre-driver 420. In some embodiments, controller 407 may be configured to implement anti-overlap logic.

As shown in FIG. 4B, low-side pre-driver 420 includes transistors 421, 422, and a resistor topology (e.g., a voltage divider or combination in series) with resistors (R1) 423, (R2) 424.

In the circuit 400 one half-bridge drives one terminal of the transformer, TX. Another copy (not shown) of the same circuit drives the other terminal of the transformer.

In operation of circuit 400, during a positive pulse, transformer terminal primary side voltage TX 418 is driven to VDRV as the HS power FET 414 is turned ON. The LS device (LS FET) 412 is OFF during this pulse. After this, LS device 412 is either turned ON (pulling TX to GNDPW) or in demagnetization mode, with TX being forced to programmable voltage, as described below.

The low-side power FET 412 is driven by pre-driver 420, which has a demagnetization operational mode. When the pre-driver Demag signal is high (at 410) the demagnetization mode is selected for pre-driver 420 and the low-side gate LSGATE 412a is connected through R1 424 to ground and through R2 423 to TX 418. In this demagnetization mode, R1 242 pulls LSGATE 412a down, while the TX node is pulled up—due to the current in the transformer flowing through the parallel combination of Resistor (R1, R2) and the ON-resistance (R_{ON}) of the LS FET 412. The TX voltage elevation is kept under control by the fact that an increasing TX voltage results in a reduced R_{ON} of the LS switch 412 which limits the rise of the magnetisation Voltage level on the TX node 418. The generated demagnetization voltage is accordingly directly related to R1, R2 values and the V_{GS} voltage of the LS FET 412.

Circuit 400 can accordingly provide several advantages relative to prior art techniques:
(i) the power in the transformer is dissipated in the LS FET, which is a large power FET capable of handling high current; (ii) the circuit requires no other power device than the LS FET; (iii) the demagnetization voltage is easily adjusted as desired by changing R1 and R2 values, so as a result it is possible to generate a voltage easily differentiable from a pulse with VDRV amplitude; (iv) the demagnetization voltage is generated only if a current runs into the LS FET (when there is no current in the transformer, there is no need for demagnetization); and (v) the demagnetization phase starts with the LS FET ON and the demagnetization voltage rises smoothly from 0V as LSGATE slowly decays pulled down by R1, which can help to avoid oscillations in parasitic LC circuits.

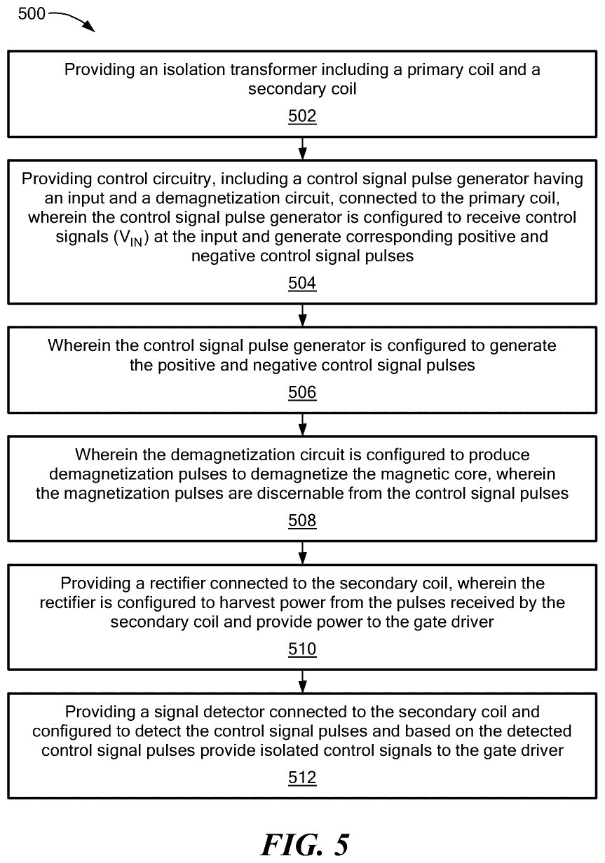

FIG. 5 is a diagram showing an example method 500 of fabricating driver circuits providing core demagnetization, in accordance with the present disclosure. Method 500 can include providing an isolation transformer including a primary coil and a secondary coil, as described at 502. Control circuitry, including a control signal pulse generator having an input and a demagnetization circuit, can be provided that is connected to the primary coil, wherein the control signal pulse generator is configured to receive control signals (V_{IN}) at the input and generate corresponding positive and negative control signal pulses, as described at 504. The control signal pulse generator can be configured to generate the positive and negative control signal pulses, as described at 506. The pulse generator may also be configured to produce refresh power pulses.

The demagnetization circuit can be configured to produce demagnetization pulses to demagnetize (e.g., reduce or prevent saturation of) the magnetic core, wherein the magnetization pulses are discernable from the control signal pulses, as described at 508. A rectifier can be provided that is connected to the secondary coil, wherein the rectifier is configured to harvest power from the pulses received by the secondary coil and provide power to the gate driver, as described at 510. A signal detector can be provided that is connected to the secondary coil and configured to detect the control signal pulses and based on the detected control signal pulses provide isolated control signals to the gate driver, as described at 512.

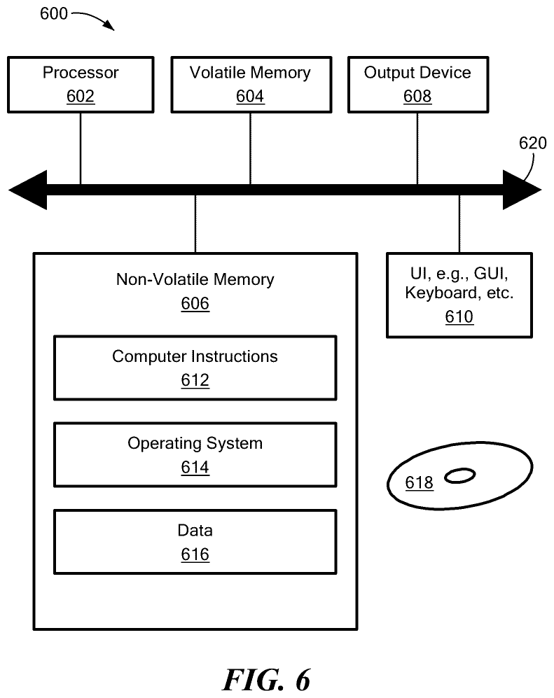

FIG. 6 shows an example computing system 600 in accordance with the present disclosure. System 600 (and/or similar or equivalent systems) can perform all or at least a portion of the processing, e.g., steps in the algorithms and methods as described herein. Such processing can include but is not limited to: controlling timing of refresh pulses delivered to high-side (or low-side) switching devices (e.g., power transistors); and/or controlling timing of demagnetization pulses delivered to low-side (or high-side) switching devices (e.g., power transistors).

The computer system 600 can include a processor 602, a volatile memory 604, a non-volatile memory 606 (e.g., hard disk), an output device 608 and a user input or interface (UI) 610, e.g., graphical user interface (GUI), a mouse, a keyboard, a display, and/or any common user interface, etc. The non-volatile memory (non-transitory storage medium) 606 stores computer instructions 612 (a.k.a., machine-readable instructions or computer-readable instructions) such as software (computer program product), an operating system 614 and data 616. In one example, the computer instructions 612 are executed by the processor 602 out of (from) volatile memory 604. In one embodiment, an article/apparatus 618 (e.g., a storage device or medium such as a hard disk, an optical disc, magnetic storage tape, optical storage tape, flash drive, etc.) includes or stores the non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), and optionally at least one input device, and one or more output devices. Program code may be applied to data entered using an input device or input connection (e.g., port or bus) to perform processing and to generate output information.

The system 600 can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer. Processing may also be implemented as a machine-readable storage medium, configured with a computer program, where upon execution, instructions in the computer program cause the computer to operate.

Processing may be performed by one or more programmable processors executing one or more computer programs to perform the functions of the system. All or part of the system may be implemented as special purpose logic circuitry, e.g., an FPGA (field programmable gate array) and/or an ASIC (application-specific integrated circuit).

Accordingly, embodiments and/or examples of the inventive subject matter can afford various benefits relative to prior art techniques. For example, embodiments and examples of the present disclosure can one or more of the following: (i) the power in the transformer is dissipated in the low-side switching device (LS FET), which can be a large power FET capable of handling high current; (ii) the circuit requires no other power device than the low-side switching device (LS FET); (iii) the demagnetization voltage is easily adjusted as desired by changing low-side pre-driver resistor (R1 and R2) values, so as a result it is possible to generate a voltage easily differentiable from a pulse with VDRV amplitude; (iv) the demagnetization voltage is generated only if a current runs into the low-side switching device (LS FET) (when there is no current in the transformer, there is no need for demagnetization); and/or (v) the demagnetization phase starts with the low-side switching device (LS FET) ON and the demagnetization voltage rises smoothly (e.g., monotonically) from 0V as LSGATE slowly decays pulled down by the low-side pre-driver resistor (R1), which can help to avoid oscillations in parasitic LC circuits.

Various embodiments of the concepts, systems, devices, structures, and techniques sought to be protected are described above with reference to the related drawings. Alternative embodiments can be devised without departing from the scope of the concepts, systems, devices, structures, and techniques described. For example, in some embodiments, primary and/or secondary transformer coils may have a whole number or a fractional number of turns (loops or structures configured around a related magnetic core), e.g., 1.5, 2.5, 1.75, 1.8, 2.25, 5, 6.5, 8.8, etc.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” may indicate any integer number greater than or equal to one, i.e., one, two, three, four, etc. ; those terms, however, may refer to fractional numbers/values where context admits, e.g., a number of loops in a transformer coil may be a plurality that includes a fractional value, e.g., 1.3, 2.75, 3.8, 4.25, etc. The term “plurality” may indicate any integer number greater than or equal to two, i.e., two, three, four, etc. ; that term, however, may refer to fractional numbers/values greater than one, e.g., 1.2, 1.8, 2.66, etc., where context admits. The term “connection” can include an indirect connection and a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and implemented in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A magnetically-isolated gate driver circuit providing core saturation protection, wherein the gate driver circuit is configured to control a semiconductor power switch, the circuit comprising:
an isolation transformer including a primary coil and a secondary coil configured about a magnetic core, wherein the isolation transformer provides galvanic separation of low and high sides of the gate driver circuit;
control circuitry, including a control signal pulse generator having an input and a demagnetization circuit, connected to the primary coil,
wherein the control signal pulse generator is configured to receive control signals (V_{IN}) at the input and generate corresponding positive and negative control signal pulses;
wherein the control circuitry is configured to produce refresh pulses having a first polarity and first voltage amplitude to provide necessary power for the gate driver circuit; and
wherein the demagnetization circuit is configured to produce demagnetization pulses having a second polarity and a second voltage amplitude to demagnetize the magnetic core, wherein the second polarity is opposite the first polarity and wherein second voltage amplitude is less than the first voltage amplitude;
a rectifier connected to the secondary coil, wherein the rectifier is configured to harvest power from the pulses received by the secondary coil and provide power to the high side of the gate driver circuit; and
a signal detector connected to the secondary coil and configured to detect the control signal pulses and based on the detected control signal pulses provide isolated control signals for control of the semiconductor power switch.

2. The circuit of claim 1, wherein the demagnetization circuit is configured to produce one or more demagnetization pulses after each control signal pulse is produced.

3. The circuit of claim 1, wherein each refresh pulse has a first duration and wherein each demagnetization pulse has a second duration, wherein the second duration is greater than the first duration.

4. The circuit of claim 1, wherein the demagnetization circuit includes first and second pre-drivers configured to provide demagnetization pulses of opposite polarity, respectively.

5. The circuit of claim 4, wherein the control circuitry further includes a logic unit configured to control the first and second pre-drivers.

6. The circuit of claim 4, wherein each of the first and second pre-drivers comprises a voltage divider having first and second resistors.

7. The circuit of claim 1, wherein the control signal pulse generator comprises first and second power field effect transistors (FETs).

8. The circuit of claim 7, wherein the first and second power FETs are configured to dissipate power from the demagnetization pulses.

9. The circuit of claim 1, wherein the signal detector includes a latch, wherein positive and negative pulses received from the secondary coil operate to set and reset the latch to form the control signal pulses.

10. The circuit of claim 1, further comprising a first semiconductor power switch connected to the secondary coil, wherein the gate driver circuit is configured to control operation of the first semiconductor power switch.

11. A method of making a magnetically-isolated gate driver circuit providing core saturation protection, wherein the gate driver circuit is configured to control a semiconductor power switch, the method comprising:
providing an isolation transformer including a primary coil and a secondary coil configured about a magnetic core, wherein the isolation transformer provides galvanic separation of low and high sides of the gate driver circuit;
providing control circuitry, including a control signal pulse generator having an input and a demagnetization circuit, connected to the primary coil,
wherein the control signal pulse generator is configured to receive control signals (V_{IN}) at the input and generate corresponding positive and negative control signal pulses;
wherein the control circuitry is configured to produce refresh pulses having a first polarity and a first voltage amplitude to provide necessary power for the gate driver circuit; and
wherein the demagnetization circuit is configured to produce demagnetization pulses having a second polarity and a second voltage amplitude to demagnetize the magnetic core, wherein the second polarity is opposite the first polarity and wherein second voltage amplitude is less than the first voltage amplitude;
providing a rectifier connected to the secondary coil, wherein the rectifier is configured to harvest power from the pulses received by the secondary coil and provide power to the high side of the gate driver circuit; and
providing a signal detector connected to the secondary coil and configured to detect the control signal pulses and based on the detected control signal pulses provide isolated control signals for control of the semiconductor power switch.

12. The method of claim 11, wherein the demagnetization circuit is configured to produce one or more demagnetization pulses after each control signal pulse is produced.

13. The method of claim 11, wherein each refresh pulse has a first duration and wherein each demagnetization pulse has a second duration, wherein the second duration is greater than the first duration.

14. The method of claim 11, wherein the demagnetization circuit includes first and second pre-drivers configured to provide demagnetization pulses of opposite polarity, respectively.

15. The method of claim 14, wherein the control circuitry further includes a logic unit configured to control the first and second pre-drivers.

16. The method of claim 14, wherein each of the first and second pre-drivers comprises a voltage divider having first and second resistors.

17. The method of claim 11, wherein the control signal pulse generator comprises first and second power field effect transistors (FETs).

18. The method of claim 17, wherein the first and second power FETs are configured to dissipate power from the demagnetization pulses.

19. The method of claim 11, wherein the signal detector includes a latch, wherein positive and negative pulses received from the secondary coil operate to set and reset the latch to form the control signal pulses.

20. The method of claim 11, further comprising providing a first semiconductor power switch connected to the secondary coil, wherein the gate driver circuit is configured to control operation of the first semiconductor power switch.
